(19) United States
(12) Patent Application Publication
(10) Pub. No.: US 2002/0079521 A1
(43) Pub. Date: Jun. 27, 2002

(54) Surface breakdown reduction by internal field rings and multiple poly field plates in power LDMOSFET

(75) Inventor: Ming-Te Lin, Hsin-Chu (TW)

Correspondence Address: LOWE HAUPTMAN GILMAN & BERNER, LLP, Suite 310, 1700 Diagonal Road, Alexandria, VA, 22314, US

(73) Assignee: UNITED MICROELECTRONICS CORP.

(21) Appl. No.: 09/740,805

(22) Filed: Dec. 21, 2000

(51) Int. Cl. H01L 29/76; H01L 31/062; H01L 31/113; H01L 31/119

(52) U.S. Cl. 257/288

(57) ABSTRACT

Lateral double diffusion metal oxide semiconductor field effect transistors (LDMOSFET) utilizing internal field rings and poly field plates are proposed to enhance electrical characteristic of the power devices. At least one internal field ring is built in a drift region of the device to increase depletion capability of the drift region. The field plates are formed over and insulated from the drift region and preferably at least one of the field plates is designed to be positioned directly above each P/N junction created between the drift region and each internal field ring. These field plates according to the present invention are coupled to drain region of the LDMOSFET to facilitate electrical field distribution of the device. In our preferred embodiments, the field plates are made of polysilicon, the fabrication of which is similar to the formation of polysilicon gate layer in a typical CMOS process.

### BACKGROUND OF THE INVENTION

1. Field of the Invention

The present invention relates to power LDMOSFET (lateral double diffusion metal oxide semiconductor field effect transistor) devices, and more particularly to an improved design of such devices.

2. Description of the Prior Art

Lateral double diffusion metal oxide semiconductor field effect transistors (known as LDMOS transistors) are the power devices of choice for integration into very large scale integrated circuit (VLSI) logic processes. The on-resistance per unit area is the figure of merit for a high voltage power device. Reduced surface field (RESURF) devices were introduced in the late 1970s to be incorporated with LDMOS transistors to offer the ability to achieve high OFF-state breakdown voltage. These devices are very attractive for building cost effective intelligent power designs, as they are smaller than other devices used for power applications and they can therefore reduce the area needed for the power device.

As shown in FIG. 1, a typical RESURF LDMOS device would comprise, given a P type semiconductor substrate 100, an N-type drift region 102 that surrounds an N⁺ drain 33. Relatively thick field oxide 99 is grown on a portion of the drift region 102. A relatively deep P-type implant is used to make the body of the transistor. The body 104 spaces the drift region 102 from a source region 66. A conductive gate 106 is formed over and insulated (by gate oxide 77) from the transistor body 104 to extends from the source region 66 over the body 104 to the lateral margin of the field oxide 99, and preferably extends onto a portion of this thick oxide 99.

The drift region 104 has a donor dopant concentration, which is designed to fully deplete with the transistor action from the P⁻ substrate gate at the rated voltage. However, a suitable dopant concentration for the drift region must be comparatively small to achieve fully depletion, thus, generally results in a rather low current-carrying capacity and high on-resistance of the device. The concept of adding inter field rings is therefore brought in to enhance the depleting ability of the drift region. Hsu, et al. proposed in U.S. Pat. Nos. 5,521,105 and 5,646,431 the utilization of a counter-doped island within the drift region as the inter field ring of the device. The counter-doped island, such as a P+ doped region 108 in the figure, offers the ability to reduce surface electrical field and thus improves the depletion capability of the corresponding diffusion layer, that is, the drift region. As a result, the doping concentration of the drift region is allowed to be increased and the on-resistance can then be reduced.

Nevertheless, any addition of a counter-doped region would inevitably create an additional P/N junction and adversely cause reverse bias of the device. As a result, the concentration of the counter-doped island and distance of the island from the drain region must be precisely and carefully manipulated to prevent early breakdown of the OFF-state voltage. Therefore, it would be helpful to come up with some kind of modified feature capable of reducing electrical field between the counter-doped region and the drain region so as to enhance OFF-state breakdown voltage of a RESURF LDMOS power device.

### SUMMARY OF THE INVENTION

One object of the present invention is to modulate electrical field of the drift region to enhance the electric characteristics of a power LDMOSFET.

Another object of the present invention is to provide a semiconductor device of the kind described in which the ON-resistance is considerably reduced as compared with that in a RESURF device of known structure, and in which improved OFF-state breakdown voltage is effectively achieved.

The present invention is based inter alia on the recognition of the fact that these objects can be achieved by the incorporation of a plurality of field plates insulated from and located over a drift region of a RESURF LDMOSFET. To be specific, the field plates are built on field oxide and at least one of the field plates is designed to be positioned directly above each P/N junction created between the drift region and each corresponding inter field ring. These field plates according to the present invention are coupled to the drain region of the LDMOSFET to facilitate electrical field distribution of the device. In our preferred embodiments, the field plates are made of polysilicon, the fabrication of which is similar to the formation of polysilicon gate layer in a typical CMOS process. As such, our modification of the convention LDMOSFET would be fully compatible with a regular CMOS process and therefore could be easily adapted into the existing fabrication facility.

### BRIEF DESCRIPTION OF THE DRAWINGS

For a more complete understanding of the present invention and advantages thereof, reference is now made to the following descriptions taken in conjunction with the accompanying drawings in which like reference numbers indicate like features and wherein:

FIG. 1 is a cross-sectional view of a conventional RESURF LDMOSFET device; and

FIG. 2 is a cross-sectional view of a RESURF LDMOSFET device including a counter-doped island and several poly field plates in accordance with one embodiment of the present invention.

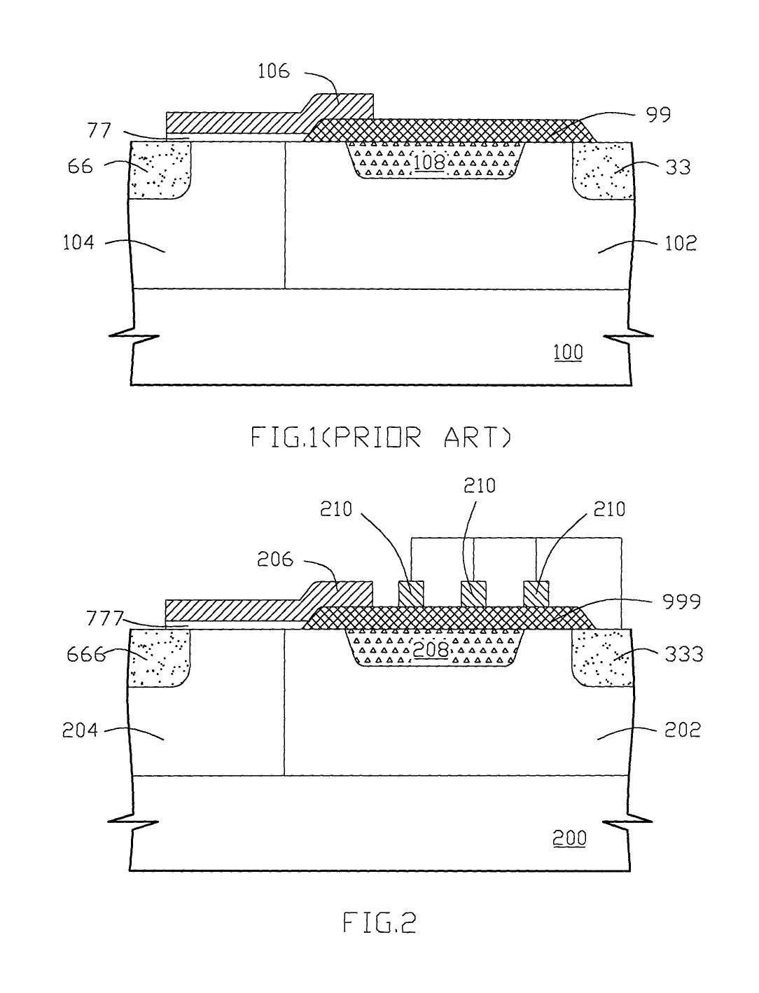

### DESCRIPTION OF THE PREFERRED EMBODIMENT

The process steps and structure described below do not form a complete process flow for manufacturing LDMOSFET. The present invention can be practiced in conjunction with LDMOSFET fabrication techniques currently used in the art, and only so much of the commonly practiced process steps are included as are necessary for an understanding of the present invention. The figures representing cross-sections of portions of a MOSFET during fabrication are not drawn to scale, but instead are drawn so as to illustrate the important features of the invention.

This invention provides an inter field ring between the source and drain of the MOSFET device to reduce surface high field and a plurality of poly field plates to distribute the electrical field evenly so as to reduce ON-resistance and increase OFF-state breakdown voltage of the device. A counter-doped island is used as the interfiled ring while polysilicon gates serve as the field plates in one preferred embodiment. Counter-doping refers to using a P dopant in an N-well. Alternatively, it could refer to using an N dopant in a P-well, if that were the embodiment being employed. The fabrication of the poly field plates is similar to that of polysilicon gate layer in a typical CMOS process.

Referring now to FIG. 2, a preferred embodiment of the present invention is described. As shown, a P-doped silicon substrate 200 containing N+ drain 333 and source regions 666 is provided. The substrate 200 also includes an N-well 202 surrounding the N+ drain 333 and a P-island along the N-well surface. The N-well 202 is referred to as a “drift region” of the device. The P island 208 forms a counter-doped region of the drift region 202 to serve as an inter field ring of the device. Above the island 208 and region 202 is a relatively thick layer of field oxide 999. A relatively deep P-type implant is used to make the body of the transistor. The body 204 spaces the drift region 202 from a source region 666. A gate electrode 206 is formed over and insulated (by gate oxide 777) from the transistor body 204 to bridge the source region 666 and the drift region 202. A plurality of field plates 210 are built on the field oxide region 999 and coupled to the drain region 333 and one of these field plates should be positioned right above a P/N junction inevitably created between the drift region 202 and counter-doped island 208. The number of field plates used herein relies on the design requirement and device limitation. In general, increase in the number of field plates could increase the field distribution ability.

In term of process steps, the P-doped substrate 200 is first N-doped to form the drift region 202. The drift region 202 is then doped to form a P-island 208 along the surface of the region 202 between the source region 333 and the drain region 666. In another embodiment, the drift region may include a number of the counter-doped islands of variable diameters along the surface. In this embodiment, formation of the counter-doped region 208 is performed by implanting dopant composed of BF₂ ions into a region where the island 208 is formed. Above the island 208 and region 202, the field oxide region 999 is formed by a conventional field oxide process. Thereafter, the gate oxide 777 is formed on top of structure surface and a layer of polysilicon is deposited thereon. The polysilicon layer is then defined by conventional photolithographic techniques to form the gate electrode and the field plates. Next, the drain 333 and source 666 are implanted with N dopant in a self-aligned manner. Once the drain region 333 is formed, the poly field plates are couple to the drain region 333 to facilitate field distribution of the device.

Although specific embodiments have been illustrated and described, it will be obvious to those skilled in the art that various modifications may be made without departing from what is intended to be limited solely by the appended claims.

What is claimed is:

1. A metal oxide semiconductor field effect transistor (MOSFET) device, said MOSFET device comprising:
a substrate having a first conductive type;
a drift region having a second conductivity type formed on said substrate;
a drain region formed in said drift region;
a counter-doped region having said first conductivity type within said drift region; and
a plurality of poly field plates positioned above said drift region, said poly field plates being coupled to said drain region.

2. The device according to claim 1, wherein said drain region has said second conductive type.

3. The device according to claim 1, further comprises a gate electrode formed over a region of said substrate extending between said source region and said drift region.

4. A metal oxide semiconductor field effect transistor (MOSFET) device, said MOSFET device comprising:
a substrate having a first conductivity type;
a drift region having a second conductivity type formed on said substrate;
a drain region formed in said drift region;
a counter-doped region having said first conductivity type surrounding said drain region;
an internal field ring within said drift region; and
a plurality of field plates positioned above said drift region, said poly field plates being coupled to said drain region.

5. The method according to claim 4, further comprises a source region and said drain region within said substrate.

6. The method according to claim 4, wherein said drain region has said second conductive type;

7. The device according to claim 4, wherein said drift region having a P/N junction.

8. The device according to claim 4, wherein said field plates comprise polysilicon field plates.
